(19) United States
(12) Patent Application Publication
(10) Pub. No.: US 2026/0044312 A1
(43) Pub. Date: Feb. 12, 2026

(54) RANDOM NUMBER GENERATION CIRCUIT AND METHOD

(71) Applicant: United Microelectronics Corp., Hsinchu (TW)

(72) Inventors: Chien-Yu KO, Tainan City (TW); Wen-Liang HUANG, Taoyuan CIty (TW); Ting-Hao CHANG, Kaohsiung City (TW); Cheng-Tung HUANG, Kaohsiung City (TW)

(21) Appl. No.: 18/817,292

(22) Filed: Aug. 28, 2024

(30) Foreign Application Priority Data
Aug. 7, 2024 (TW) 113129571

(51) Int. Cl. G06F 7/58; H10N 50/10; H10N 50/80

(52) U.S. Cl. CPC G06F 7/588; H10N 50/10; H10N 50/80

(57) ABSTRACT

The application discloses a random number generation circuit and method. The random number generation circuit includes: a magnetic tunnel junction (MTJ) including a first terminal and a second terminal; a first inverter including an input terminal receiving a clock signal, and an output terminal; a second inverter including an input terminal receiving the clock signal, and an output terminal coupled to the first terminal of the magnetic tunnel junction; and a third inverter including an input terminal coupled to the output terminal of the first inverter, and an output terminal coupled to the second terminal of the magnetic tunnel junction.

This application claims the benefit of Taiwan application Serial No. 113129571, filed August 7, 2024, the disclosure of which is incorporated by reference herein in its entirety.

### TECHNICAL FIELD

The present invention relates to a random number generation circuit and method, particularly to a random number generation circuit and method utilizing magnetic tunnel junction (MTJ) technology.

### BACKGROUND

Random number generators have important uses in many different application scenarios. Here are some common uses. (1) Password generation: Random number generators are used to create secure and hard-to-crack passwords. Randomly generated passwords can avoid the use of easily guessable words or patterns, enhancing system security. (2) Encryption key generation: In encryption systems, random numbers are used to generate encryption keys, ensuring the security and confidentiality of data transmission. (3) Testing and simulation: Used in software testing and simulations, random data can help test the performance of applications under different conditions, ensuring their stability and reliability. (4) Random sampling: In statistics and data analysis, random numbers are used for random sampling to ensure the representativeness of samples and avoid bias. (5) Game development: In games, random data can be used to generate random maps, random events, or random item drops, increasing the diversity and playability of the game. (6) Lotteries and random selection: Used in lotteries or for randomly selecting participants, ensuring fairness and randomness of the results. (7) CAPTCHA (Completely Automated Public Turing test to tell Computers and Humans Apart): Random number generators are used in web applications to generate CAPTCHA codes to prevent automated programs (such as bots) from abusing the service. (8) Privacy protection: In the process of data anonymization, random numbers can be used to replace sensitive information, protecting personal privacy. These are just some of the applications of random number generators. In fact, they play a crucial role in many fields.

Current random number generators have relatively complex circuit architectures, occupy large circuit areas, have poor Time-Dependent Dielectric Breakdown (TDDB) performance, and consume high power.

Therefore, there is a need in the industry for a random number generation circuit and method to improve upon the shortcomings of existing technologies.

### SUMMARY

According to one embodiment, a random number generation circuit is provided. The random number generation circuit includes: a magnetic tunnel junction (MTJ) including a first terminal and a second terminal; a first inverter including: an input terminal for receiving a clock signal; and an output terminal; a second inverter including: an input terminal for receiving the clock signal; and an output terminal coupled to the first terminal of the MTJ; and a third inverter including: an input terminal coupled to the output terminal of the first inverter; and an output terminal coupled to the second terminal of the MTJ.

According to another embodiment, a random number generation method applied to a random number generation circuit is provided. The random number generation circuit includes an MTJ, a first inverter, a second inverter, and a third inverter. The MTJ is coupled to the second inverter and the third inverter. The first inverter is coupled to the second inverter and the third inverter. The random number generation method comprises: in setting, a setting current flowing from the third inverter through the MTJ to the second inverter; and in resetting, a reset current flowing from the second inverter through the MTJ to the third inverter.

### BRIEF DESCRIPTION OF THE DRAWINGS

FIG. 1 illustrates a circuit diagram of a random number generation circuit according to an embodiment of the present invention.

FIGS. 2A and 2B illustrate a random number generation method according to an embodiment of the present invention.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, one skilled person in the art would selectively implement part or all technical features of any embodiment of the disclosure or selectively combine part or all technical features of the embodiments of the disclosure.

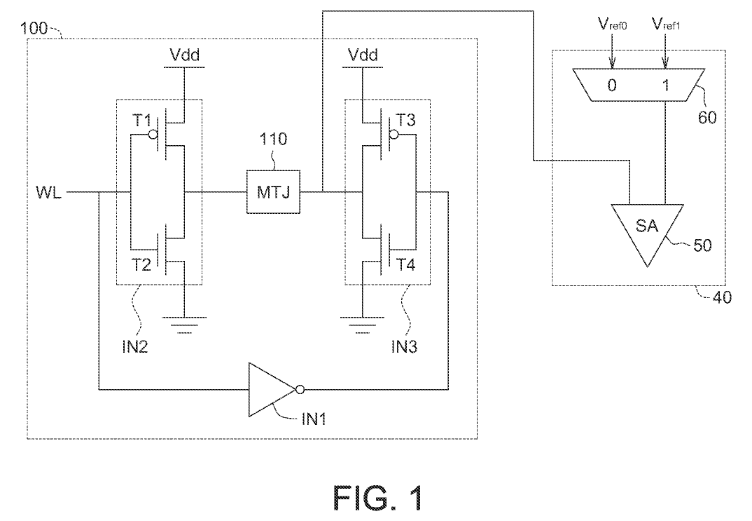

FIG. 1 illustrates a circuit diagram of a random number generation circuit according to an embodiment of the present invention. As shown in FIG. 1, the random number generation circuit 100 includes a magnetic tunnel junction (MTJ) 110, a first inverter IN1, a second inverter IN2, and a third inverter IN3. The random number generation circuit 100 is coupled to a read circuit 40, which includes a sense amplifier 50 and a multiplexer 60. The sense amplifier 50 is coupled to the MTJ 110 of the random number generation circuit 100. The multiplexer 60 is coupled to the sense amplifier 50.

The MTJ 110 includes a first terminal and a second terminal. As is known, by adjusting a setting current passing through the MTJ 110, the success rate of setting (writing logic 1) in the MTJ 110 can be controlled.

The first inverter IN1 includes an input terminal for receiving a clock signal WL and an output terminal.

The second inverter IN2 includes an input terminal for receiving the clock signal WL and an output terminal coupled to the first terminal of the MTJ 110.

The third inverter IN3 includes an input terminal coupled to the output terminal of the first inverter IN1 and an output terminal coupled to the second terminal of the MTJ 110.

The second inverter IN2 includes a first transistor T1 and a second transistor T2.

The first transistor T1 includes a first terminal for receiving an operating voltage Vdd, a second terminal coupled to the first terminal of the MTJ 110, and a control terminal for receiving the clock signal WL.

The second transistor T2 includes a first terminal coupled to a ground terminal, a second terminal coupled to the first terminal of the MTJ 110, and a control terminal for receiving the clock signal WL.

The third inverter IN3 includes a third transistor T3 and a fourth transistor T4.

The third transistor T3 includes a first terminal for receiving the operating voltage Vdd, a second terminal coupled to the second terminal of the MTJ 110, and a control terminal coupled to the output terminal of the first inverter IN1.

The fourth transistor T4 includes a first terminal coupled to the ground terminal, a second terminal coupled to the second terminal of the MTJ 110, and a control terminal coupled to the output terminal of the first inverter IN1.

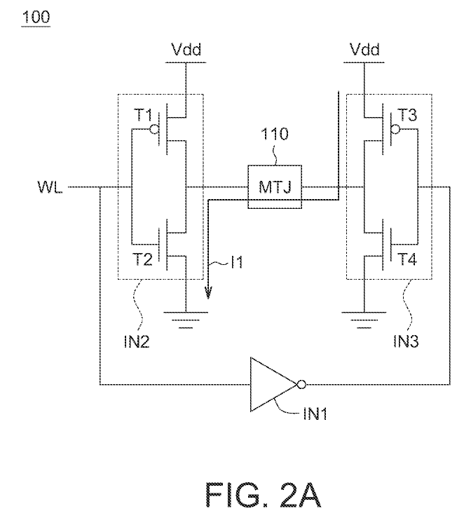

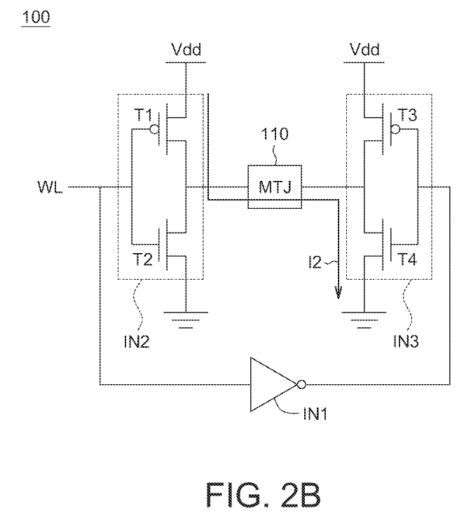

FIGS. 2A and 2B illustrate a random number generation method according to an embodiment of the present invention.

As shown in FIG. 2A, during the setting process, a setting current I1 flows from the third inverter IN3 through the magnetic tunnel junction (MTJ) 110 to the second inverter IN2. Specifically, during the setting process, the clock signal WL is a first logic signal (logic 1), which turns on the second transistor T2. An output signal from the first inverter IN1 turns on the third transistor T3, causing the setting current I1 to flow from the third transistor T3 through the MTJ 110 to the second transistor T2.

As shown in FIG. 2B, during the reset process, a reset current I2 flows from the second inverter IN2 through the MTJ 110 to the third inverter IN3. Specifically, during the reset process, the clock signal WL is a second logic signal (logic 0), which turns on the first transistor T1. An output signal from the first inverter IN1 turns on the fourth transistor T4, causing the reset current I2 to flow from the first transistor T1 through the MTJ 110 to the fourth transistor T4.

When generating random numbers, the sense amplifier 50 reads the MTJ 110 and compares to a reference voltage Vref0 or Vref1 to determine whether the stored value in the MTJ 110 is logic 1 or logic 0. When setting the MTJ 110, the success rate might be 50% or 60%, etc. Therefore, the values read from the MTJ 110 will be random numbers.

With the random number generation circuit and method of the described embodiment, the circuit architecture is relatively simple (including six transistors and one MTJ, with each of the three inverters comprising two transistors), thus occupying a smaller circuit area and consuming less power.

Additionally, with the random number generation circuit and method of the described embodiment, since the voltage of the clock signal WL is relatively low, the Time-Dependent Dielectric Breakdown (TDDB) performance of the described embodiment is better.

Although many specific details are described in this disclosure, they should not be understood as limitations on the scope of the claimed invention, but rather as descriptions of specific characteristics of particular embodiments. Certain features described in the context of a single embodiment can also be implemented in combination in a single embodiment. Conversely, various features described in the context of a single embodiment can be implemented individually or in any suitable sub-combination in multiple embodiments. Furthermore, while features may initially be described as functioning in certain combinations, or initially described as being illustrated in a certain sequence, it should be understood that in some cases, one or more features might be removed from the combination, and the described combination may still function as a sub-combination or variation of a sub-combination. Similarly, although operations are depicted in a specific sequence in the illustrations, this should not be understood as requiring that such operations be performed in the specific illustrated sequence or order, or that all illustrated operations must be performed to achieve desired results.

While the above-described embodiments disclose only some examples and implementations, modifications, alterations, and enhancements can be made to the disclosed examples and implementations and other implementations based on the disclosed content.

In summary, while the invention has been described above in conjunction with specific embodiments, it is not limited to those embodiments. Those skilled in the relevant art, without departing from the spirit and scope of the invention, can make various changes and modifications. Therefore, the scope of the invention should be defined by the appended claims.

What is claimed is:

1. A random number generation circuit, comprising:
a magnetic tunnel junction (MTJ) including a first terminal and a second terminal;
a first inverter including: an input terminal for receiving a clock signal; and an output terminal;
a second inverter including: an input terminal for receiving the clock signal; and an output terminal coupled to the first terminal of the MTJ; and
a third inverter including: an input terminal coupled to the output terminal of the first inverter; and an output terminal coupled to the second terminal of the MTJ.

2. The random number generation circuit according to claim 1, wherein
the second inverter includes a first transistor and a second transistor;
the first transistor includes: a first terminal for receiving an operating voltage; a second terminal coupled to the first terminal of the MTJ; and a control terminal for receiving the clock signal; and
the second transistor includes: a first terminal coupled to a ground terminal; a second terminal coupled to the first terminal of the MTJ; and a control terminal for receiving the clock signal.

3. The random number generation circuit according to claim 2, wherein
the third inverter includes a third transistor and a fourth transistor;
the third transistor includes: a first terminal for receiving the operating voltage; a second terminal coupled to the second terminal of the MTJ; and a control terminal coupled to the output terminal of the first inverter; and
the fourth transistor includes: a first terminal coupled to the ground terminal; a second terminal coupled to the second terminal of the MTJ; and a control terminal coupled to the output terminal of the first inverter.

4. A random number generation method applied to a random number generation circuit, wherein the random number generation circuit includes an MTJ, a first inverter, a second inverter, and a third inverter, the MTJ coupled to the second inverter and the third inverter, and the first inverter coupled to the second inverter and the third inverter, the random number generation method comprising:
in setting, a setting current flowing from the third inverter through the MTJ to the second inverter; and
in resetting, a reset current flowing from the second inverter through the MTJ to the third inverter.

5. The random number generation method according to claim 4, wherein
the MTJ includes a first terminal and a second terminal;
the first inverter includes: an input terminal for receiving a clock signal; and an output terminal;
the second inverter includes a first transistor and a second transistor;
the third inverter includes a third transistor and a fourth transistor;
the first transistor includes: a first terminal for receiving an operating voltage; a second terminal coupled to the first terminal of the MTJ; and a control terminal for receiving the clock signal;
the second transistor includes: a first terminal coupled to a ground terminal; a second terminal coupled to the first terminal of the MTJ; and a control terminal for receiving the clock signal;
the third transistor includes: a first terminal for receiving the operating voltage; a second terminal coupled to the second terminal of the MTJ; and a control terminal coupled to the output terminal of the first inverter; and
the fourth transistor includes: a first terminal coupled to the ground terminal; a second terminal coupled to the second terminal of the MTJ; and a control terminal coupled to the output terminal of the first inverter.

6. The random number generation method according to claim 5, wherein
in setting, the clock signal is a first logic signal, the clock signal turns on the second transistor, an output signal from the first inverter turns on the third transistor, and the setting current flows from the third transistor through the MTJ to the second transistor.

7. The random number generation method according to claim 5, wherein in resetting, the clock signal is a second logic signal, the clock signal turns on the first transistor, an output signal from the first inverter turns on the fourth transistor, and the reset current flows from the first transistor through the MTJ to the fourth transistor.
